(19) United States
(12) Patent Application Publication
(10) Pub. No.: US 2002/0180561 A1
(43) Pub. Date: Dec. 5, 2002

(54) Laminated filter, integrated device, and communication apparatus

(76) Inventors: Emiko Kawahara, Osaka (JP); Toru Yamada, Osaka (JP); Tsutomu Matsumura, Osaka (JP)

Correspondence Address: RATNERPRESTIA, P O BOX 980, VALLEY FORGE, PA, 19482-0980, US

(21) Appl. No.: 10/145,065

(22) Filed: May 14, 2002

(30) Foreign Application Priority Data
May 16, 2001 (JP) 2001-146975

(51) Int. Cl. H03H 7/01

(52) U.S. Cl. 333/175

(57) ABSTRACT

(Object)

To provide a laminated band-pass filter comprising at least two band-pass filters without reducing the Q factor of strip line conductors constituting the band-pass filters.

(Constitution)

A laminated band-pass filter comprises an integrated device formed by laminating and integrating a plurality of dielectric layers 101 to 110 together, a plurality of internal grounding conductors 119, 137, and 142 formed inside the integrated device, and two band-pass filters sandwiched between two 119 and 137 of the plurality of grounding conductors and formed inside the integrated device. One of the band-pass filters has strip line conductors 128 and 129, and the other has strip line conductors 131 and 132. The two band-pass filters are formed in different areas with a boundary between these areas corresponding to a predetermined cross section substantially perpendicular to the grounding conductors.

### BACKGROUND OF THE INVENTION

1. Field of the Invention

The present invention relates to a laminated filter, integrated device, and communication apparatus which are used in high-frequency radio equipment such as a cellular telephone.

2. Related Art of the Invention

In recent years, owing to a continued reduction in size of communication equipment, dielectric laminated filters, which are effective in size reduction, have often been used as high frequency filters. An example of such a laminated band-pass filter will be described with reference to the drawings.

FIG. 4 is a sectional view of a conventional laminated band-pass filter 400. In this figure, the laminated band-pass filter 400, formed by laminating and integrating a plurality of dielectric layers together, is sandwiched between internal grounding conductors 401 and 402, and a first band-pass filter 404 is formed on a top surface of the internal grounding conductor 401, with an internal grounding conductor 403 arranged on the first band-pass filter and a second band-pass filter 405 formed on the internal grounding conductor 403. Strip line conductors 410 are provided substantially in the center of each of the first and second band-pass filters 404 and 405 in a thickness direction thereof.

The first and second band-pass filters 404 and 405 are laminated together while being shielded by the internal grounding conductor 403, thereby reducing the interference between the two filters.

However, in the above described configuration, the interval between the internal grounding conductors sandwiching the corresponding one of the first and second band-pass filters 404 and 405 therebetween (i.e. the interval between the internal grounding conductors 402 and 403 and the interval between the internal grounding conductors 401 and 403) is smaller than that between interval between internal grounding conductors for a single band-pass filter 501 formed inside an integrated device (i.e. the interval between internal grounding conductors 511 and 512).

For comparison, the sectional view in FIG. 5 shows a conventional laminated band-pass filter 500 having the band-pass filter 501.

In FIG. 5, the single band-pass filter 501, formed inside an integrated device having a thickness d, is sandwiched between the internal grounding conductors 511 and 512. Strip line conductors 510 (see FIG. 5) are provided substantially in the center of the band-pass filter 501 in the thickness direction thereof.

The inventors have found that in the first and second band-pass filters 404 and 405, the Q factor of the strip line conductors, which constitute the band-pass filter, may decrease to increase an insertion loss to this device compared to the band-pass filter 501.

More specifically, as shown in FIG. 10 illustrating simulation-based analysis of the behavior of the Q factor of a high-frequency resonance circuit which behavior is observed when the shield interval is varied, when the high-frequency resonance circuit uses a frequency of 1,200 MHz, its Q factor is (1) about 38 if the shield interval (corresponding to the thickness d, described previously) is 0.6 mm and decreases to (2) about 26 if the shield interval is 0.4 mm. This high-frequency resonance circuit is constructed similarly to the laminated band-pass filter 500 described previously (see FIG. 5), and the strip line conductors are provided substantially in the center of the band-pass filter in the thickness direction thereof.

### SUMMARY OF THE INVENTION

In view of the above described problems, it is an object of the present invention to provide a small-sized and small-loss laminated filter, integrated device, and communication apparatus.

The 1st invention of the present invention is a laminated filter comprising:

a plurality of grounding conductors formed inside or outside a integrated device formed by laminating and integrating a plurality of dielectric layers together;

a first filter sandwiched between two of said grounding conductors which have a shielding function; and

a second filter sandwiched between said two grounding conductors.

The 2nd invention of the present invention is the laminated filter according to 1st invention, wherein said first filter is a band-pass filter, and

said second filter is a band-pass filter.

The 3rd invention of the present invention is the laminated filter according to 2nd invention, wherein said first filter and said second filter are formed in different areas with a boundary between these areas corresponding to a predetermined cross section substantially perpendicular to said two grounding conductors.

The 4th invention of the present invention is the laminated filter according to 3rd invention, further comprising a shielding conductor formed substantially in said predetermined cross section and connected to said plurality of grounding conductors to shield electromagnetic induction between said first filter and said second filter.

The 5th invention of the present invention is the laminated filter according to 4th invention, wherein via conductors are used to connect the shielding conductor to said grounding conductors.

The 6th invention of the present invention is the laminated filter according to 2nd invention, wherein some of said plurality of grounding conductors are formed inside said integrated device,

said first filter has a plurality of input and output terminals formed inside or outside said integrated device, a grounding terminal formed inside or outside said integrated device, a capacitive conductor formed inside said integrated device, and a plurality of strip line conductors formed inside said integrated device,

said grounding terminal is electrically connected to the grounding conductors formed inside said integrated device, and

said plurality of strip line conductors each have one end electrically connected to said capacitive conductor and the other end electrically connected to the grounding conductors formed inside said integrated device.

The 7th invention of the present invention is the laminated filter according to 6th invention, wherein said plurality of strip line conductors are two strip line conductors installed in parallel, and

the other ends of said two parallel strip line conductors are not adjacent to each other.

The 8th invention of the present invention is the laminated filter according to 6th invention, wherein said plurality of input and output terminals are two input and output terminals installed in proximity to each other,

said grounding terminal is provided between said two input and output terminals installed in proximity to each other.

The 9th invention of the present invention is the laminated filter according to 6th invention, wherein said second filter has a plurality of input and output terminals formed inside or outside said integrated device, and

a plurality of input and output terminals of said first filter and a plurality of input and output terminals of said second filter are provided in the same layer of said integrated device symmetrically with respect to the center of said layer.

The 10th invention of the present invention is the laminated filter according to 6th invention, further comprising a predetermined circuit element electrically connected to said plurality of input and output terminals.

The 11th invention of the present invention is the laminated filter according to 2nd invention, wherein said first filter has a layer having a resonator capacitive conductor required to constitute a resonator, a layer having input and output capacitive conductors connected to the input and output terminals, and a layer having an interstage capacitive conductor or a cross coupling capacitive conductor,

said second filter has a layer having a resonator capacitive conductor required to constitute a resonator, a layer having input and output capacitive conductors connected to the input and output terminals, and a layer having an interstage capacitive conductor or a cross coupling capacitive conductor,

(a) the layer having the resonator capacitive conductor of said first filter and the layer having the resonator capacitive conductor of said second filter are present in different layers of said integrated device, (b) the layer having the input and output capacitive conductors of said first filter and the layer having the input and output capacitive conductors of said second filter are present in different layers of said integrated device, or (c) the layer having the interstage capacitive conductor or cross coupling capacitive conductor of said first filter and the layer having the interstage capacitive conductor or cross coupling capacitive conductor of said second filter are present in different layers of said integrated device.

The 12th invention of the present invention is the laminated filter according to 2nd invention, wherein said first filter has a plurality of strip line conductors formed substantially midway between said two grounding conductors in a thickness direction of said integrated device.

The 13th invention of the present invention is the laminated filter according to 2nd invention, wherein said first filter has a plurality of capacitive conductors and a plurality of strip line conductors, and

of said plurality of capacitive conductors, the interstage capacitive conductor, cross coupling capacitive conductor, and input and output capacitive conductors are formed substantially midway between either of said two grounding conductors and said plurality of strip line conductors in the thickness direction of said integrated device.

The 14th invention of the present invention is the laminated filter according to 2nd invention, wherein said first filter has a plurality of capacitive conductors and a plurality of strip line conductors, and

a predetermined one of those of said plurality of capacitive conductors which are connected to said strip line conductors electrically in parallel is formed opposite either of said two grounding conductors.

The 15th invention of the present invention is the laminated filter according to 14th invention, further comprising a predetermined grounding conductor formed so that said predetermined capacitive conductor is sandwiched between said predetermined grounding conductor and either of said two grounding conductors.

The 16th invention of the present invention is the laminated filter according to 2nd invention, wherein said first filter and said second filter use different frequency bands as pass bands.

The 17th invention of the present invention is the laminated filter according to 16th invention, wherein one of said first and second filters which use a lower frequency band as a pass band has a larger occupied volume in said integrated device.

The 18th invention of the present invention is the laminated filter according to 2nd invention, wherein a crystal phase forming the dielectric layers of said integrated device has any of Al₂O₃, MgO, SiO₂, and ROa for R denoting at least one of La, Ce, Pr, Nd, Sm, and Gd and a denoting a numerical value stoichiometrically determined depending on the valence of said R.

The 19th invention of the present invention is the laminated filter according to 1st invention, wherein said first filter is a band-pass filter, and said second filter is a band elimination filter.

The 20th invention of the present invention is the laminated filter according to 1st invention, wherein said first filter is a band elimination filter, and

said second filter is a band elimination filter.

The 21st invention of the present invention is a integrated device comprising:

said integrated device containing the laminated filter according to 1st invetnion, and

an integrated circuit mounted in said integrated device.

The 22nd invention of the present invention is a communication apparatus comprising:

transmitting and receiving means of executing transmission and/or reception, and

the laminated filter according to 1st invention which filters a transmitted signal used for said transmission and/or a received signal used for said reception.

### BRIEF DESCRIPTION OF THE DRAWINGS

FIG. 1 is an exploded perspective view of a laminated band-pass filter according to Embodiment 1 of the present invention.

FIG. 2(a) is an equivalent circuit diagram of a band-pass filter according to Embodiments 1 and 2 of the present invention, and FIG. 2(b) is an equivalent circuit diagram of a band-pass filter according to Embodiments 1 and 3 of the present invention.

FIG. 3 is an exploded perspective view of a laminated band-pass filter according to Embodiment 2 of the present invention.

FIG. 4 is a sectional view of a conventional laminated band-pass filter 400.

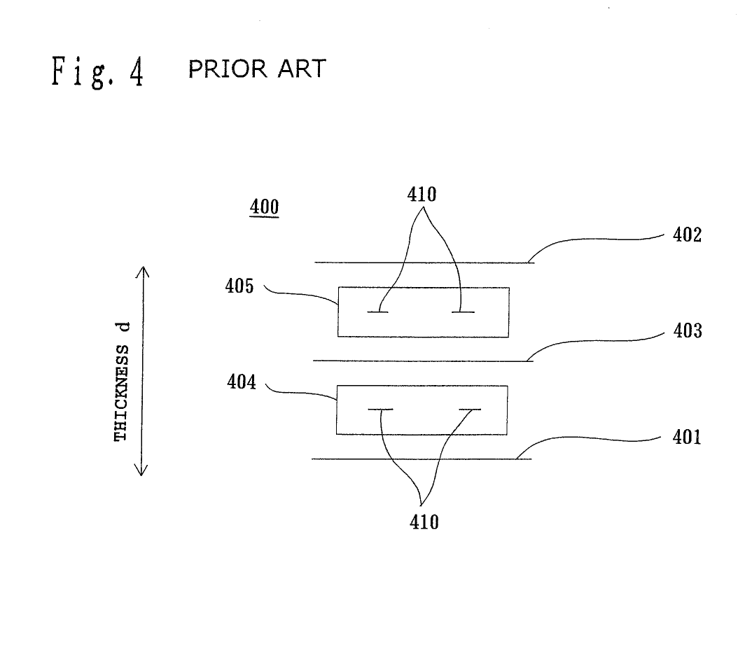

FIG. 5 is a sectional view of a conventional laminated band-pass filter 500.

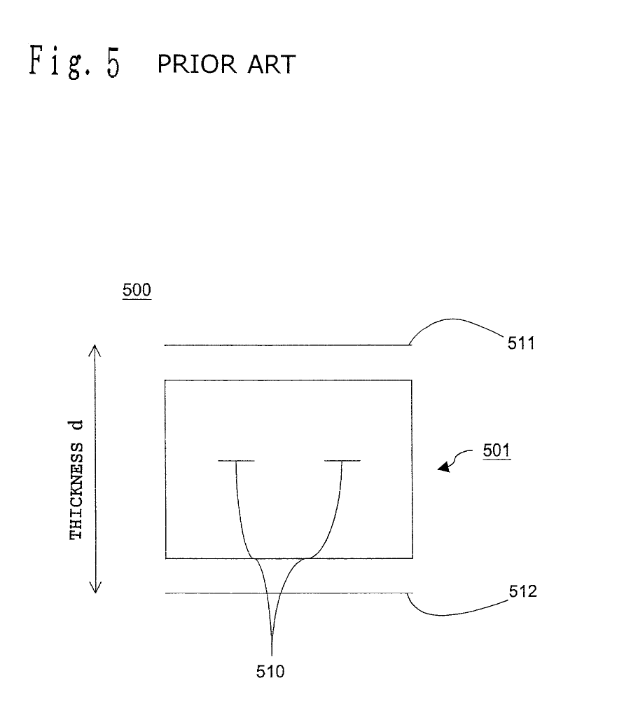

FIG. 6 is an exploded perspective view of a laminated band-pass filter according to Embodiment 3 of the present invention.

FIG. 7 is an equivalent circuit diagram of a band elimination filter according to Embodiment 3 of the present invention.

FIG. 8 is a diagram illustrating another example of a laminated structure of the laminated band-pass filter according to Embodiment 1 of the present invention.

FIG. 9 is a diagram showing the configuration of a communication apparatus according to an embodiment of the present invention.

FIG. 10 is a chart illustrating simulation-based analysis of the behavior of the Q factor of a high-frequency resonance circuit which behavior is observed when shield interval is varied.

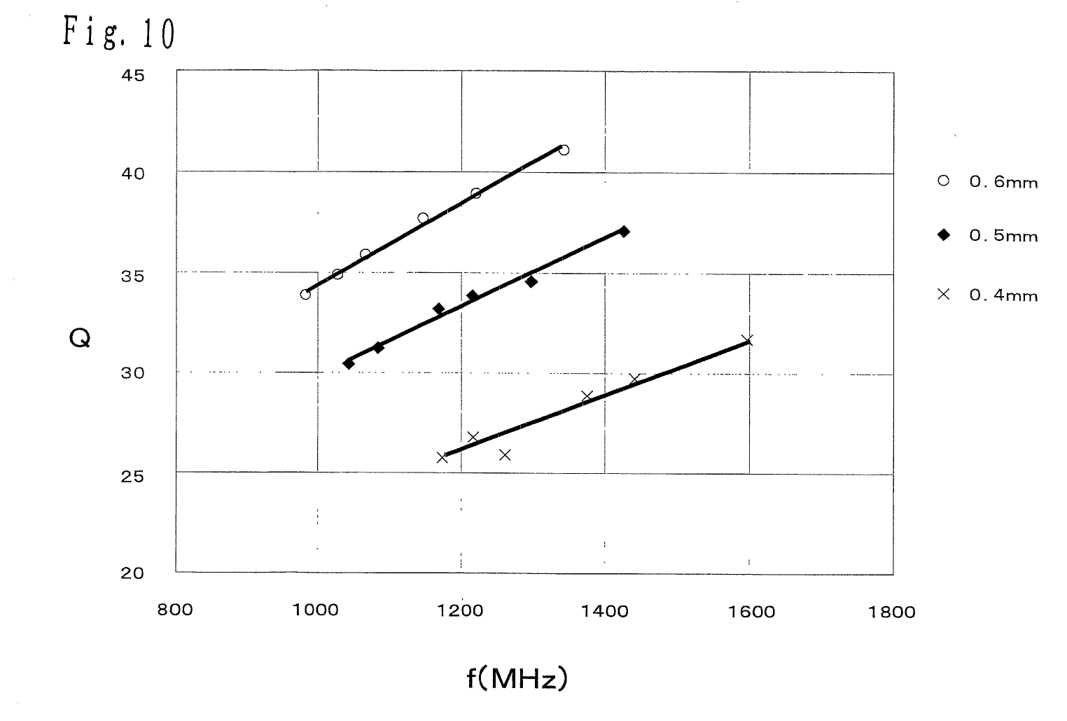

### DESCRIPTION OF SYMBOLS

101 to 110, 301 to 311 Dielectric layers

111 to 114, 312 to 315 Input and output terminals

115 to 118, 316 to 319 Grounding terminals

119, 137, 142, 320, 340, 343 Internal grounding conductors

120 to 127, 133 to 136, 139 to 141, 321 to 328, 334 to 339,

341, 342 Capacitive conductors

128 to 132, 329 to 333 Strip line conductors

201 to 204, 208 to 212, 216 Capacitances

205, 206, 211, 212 Inductors

207, 215 Mutual inductors

### PREFERRED EMBODIMENTS OF THE INVENTION

A laminated band-pass filter according to an embodiment of the present invention will be described below with reference to the drawings.

(Embodiment 1)

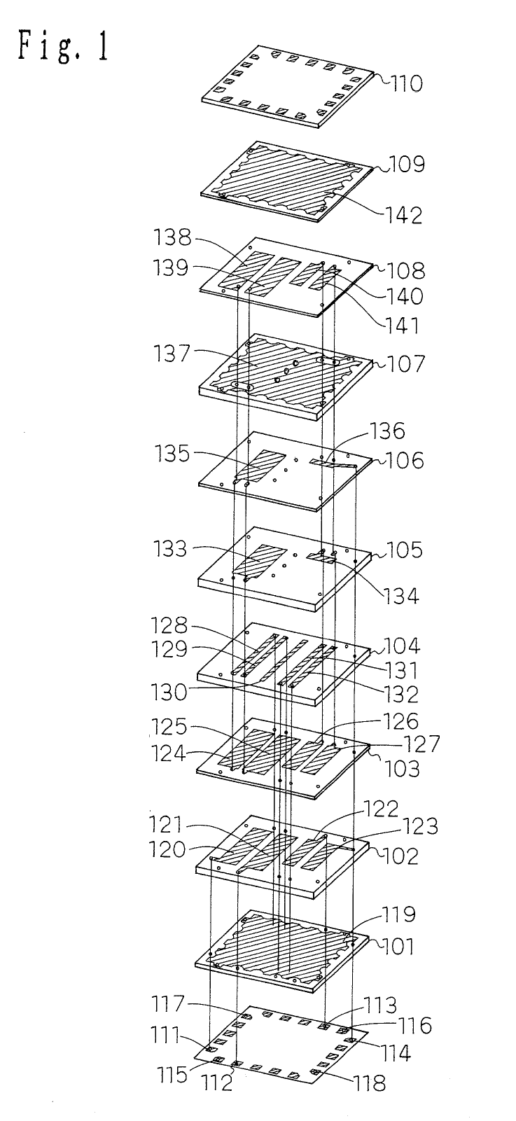

FIG. 1 is an exploded perspective view of a laminated band-pass filter according to Embodiment 1 of the present invention.

The laminated band-pass filter of this embodiment is characterized in that it is possible to provide such a design that a (1) first band-pass filter (in the left of the drawing) having strip line conductors 128 and 129 spaced at a given interval and electromagnetically coupled together and a (2) second band-pass filter (in the right of the drawing) having strip line conductors 131 and 132 spaced at a given interval and electromagnetically coupled together are not disposed in the direction of laminating but in the direction perpendicular thereto, so that there is a sufficient interval between outermost internal grounding conductors 119 and 142 sandwiching the first and second band-pass filters therebetween and functioning as shield layers, thereby suppressing a decrease in Q factor of each of the strip line conductors 128, 129, 131, and 132.

As shown in FIG. 1, the laminated band-pass filter according to Embodiment 1 of the present invention comprises sequentially laminated dielectric layers 101 to 110, and the integrated device has a size of 5.0×5.0 mm and a height of 0.8 mm. Further, each dielectric layer is composed of a crystal phase having a dielectric constant εr of 7 and a glass phase. The crystal phase is composed of Mg₂SiO₄, whereas the glass phase is composed of Si—Ba—La—B—O-system. The integrated device has input and output terminals 111 to 114 and grounding terminals 115 to 118 formed on a bottom surface thereof.

The dielectric layers 101, 107, and 109 have internal grounding conductors 119, 137, and 142, respectively, arranged on top surfaces thereof and connected to the grounding terminals 115 to 118 via via conductors. The dielectric layer 102 has capacitive conductors 120 to 123 arranged on a top surface thereof and connected to the input and output terminals 111 to 114, respectively, via via conductors. The dielectric layer 103 has capacitive conductors 124 to 127 arranged on a top surface thereof, and the dielectric layer 104 has strip line conductors 128 to 132 arranged on a top surface thereof. Further, the dielectric layer 105 has capacitive conductors 133 and 134 arranged on a top surface thereof, the dielectric layer 106 has capacitive conductors 135 and 136 arranged on a top surface thereof, and the dielectric layer 108 has capacitive conductors 138 to 141 arranged on a top surface thereof.

Furthermore, the strip line conductor 128 has one end thereof connected to the internal grounding conductor 119 via a via conductor and the other end thereof connected to each of the capacitive conductors 124, 135, and 138 via a via conductor. Likewise, the strip line conductor 129 has one end thereof connected to the internal grounding conductor 119 via a via conductor and the other end thereof connected to each of the capacitive conductors 125, 133, and 139 via a via conductor. The strip line conductor 131 has one end thereof connected to the internal grounding conductor 119 via a via conductor and the other end thereof connected to each of the capacitive conductors 126, 134, and 140 via a via conductor. The strip line conductor 132 has one end thereof connected to the internal grounding conductor 119 via a via conductor and the other end thereof connected to each of the capacitive conductors 127 and 141 via a via conductor.

Further, the capacitive conductor 136 is arranged opposite the capacitive conductor 134 and connected to the input and output terminal 114 via a via conductor. The strip line conductor 130 is connected to the internal grounding conductor 137 via three via conductors penetrating three via holes formed at the boundary between the first and second band-pass filters.

The strip line conductor 130 corresponds to a shielding conductor according to the present invention, and the input and output terminals 111 to 114 correspond to input and output terminals according to the present invention. The grounding terminals 115 to 118 correspond to grounding terminals according to the present invention, the capacitive conductors 120 to 127, 133 to 136, and 139 to 141 correspond to capacitive conductors according to the present invention, and the strip line conductors 128 to 132 correspond to strip line conductors according to the present invention. Further, the dielectric layers 101 to 110 correspond to dielectric layers according to the present invention, the internal grounding conductors 119, 137, and 142 correspond to grounding conductors according to the present invention, and the internal grounding conductors 119 and 142 correspond to two grounding conductors according to the present invention having a shielding function.

In this case, the internal grounding conductor 137 is not used for shielding and is not essential. However, the internal grounding conductor 137 is capacitively coupled to the capacitive conductors 138 to 141 and has a function for keeping the capacitances of the capacitive conductors 138 to 141 sufficient even if the stack is used in a high-frequency band.

As shown in FIG. 1, the strip line conductor 130, which operates as a shielding conductor, is provided between the strip line conductors 128 and 129 and the strip line conductors 131 and 132, each pair of strip conductors constituting the corresponding band-pass filter. This arrangement hinders the two laminated band-pass filters from affecting each other, while ensuring that these band-pass filters are isolated from each other.

Further, the strip line conductors 128, 129, 131, and 132, which constitute the two laminated band-pass filters, are arranged substantially midway between the internal grounding conductors 119 and 137. This arrangement hinders the Q factor of the strip line conductors from decreasing, thereby providing a laminated band-pass filter undergoing a small insertion loss.

Further, the capacitive conductors 120 to 127, which form capacitances 201 and 202 as well as 209 and 210, are arranged substantially midway between the strip line conductor layer and the internal grounding conductor 119, and the capacitive conductors 133 to 136, which form capacitances 208 and 216, are arranged substantially midway between the strip line conductor layer and the internal grounding conductor 137. This arrangement hinders the Q factor of the capacitance provided by each capacitive conductor from decreasing, thereby providing a laminated band-pass filter undergoing a small insertion loss.

Furthermore, the capacitive conductors 138 to 141 are arranged opposite the grounding conductors 137 and 142, and the capacitive conductors 138 to 141 are sandwiched between the two grounding conductors 137 and 142. This arrangement enables a capacitive conductor layer to be omitted to reduce the height of the device, and also enables larger capacitances to be formed to increase the degree of freedom of design.

Moreover, the grounding terminal 115 is provided between the input and output terminals 111 and 112 of the first band-pass filter, and the grounding terminal 116 is provided between the input and output terminals 113 and 114 of the second band-pass filter to ensure the isolation between the input and output terminals of the band-pass filters. Further, the pair of input and output terminals 111 and 112 of the first band-pass filter and the pair of input and output terminals 113 and 114 of the second band-pass filter are arranged symmetrically with respect to the center of the integrated device, thereby ensuring that the two band-pass filters are isolated from each other.

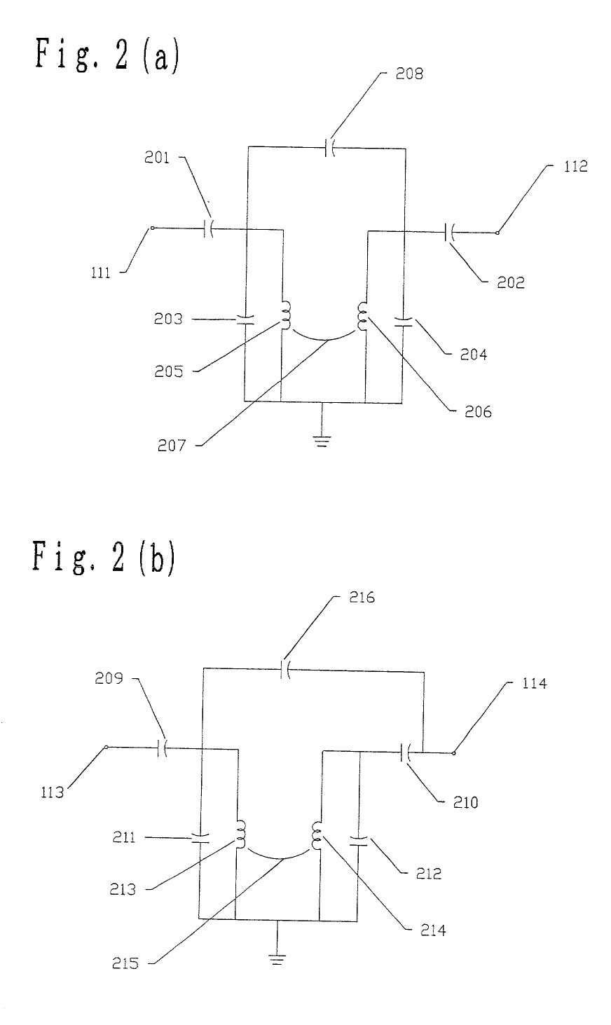

Then, the circuit configuration of the laminated band-pass filter constructed as described above will be described with reference to FIGS. 2(a) to 2(b).

FIGS. 2(a) and 2(b) show equivalent circuits of the first and second band-pass filters, respectively, in FIG. 1. Those elements in FIGS. 2(a) and 2(b) which correspond to FIG. 1 are denoted by the same reference numerals.

The former circuit configuration (see FIG. 2(a)) forms an attenuating pole on a low-frequency side of a pass band, whereas the latter circuit configuration (see FIG. 2(b)) forms an attenuating pole on a high-frequency side of a pass band. Accordingly, in this embodiment, the former circuit configuration (see FIG. 2(a)) is used for the first band-pass filter, whereas the latter circuit configuration (see FIG. 2(b)) is used for the second band-pass filter. However, the present invention is not limited to this aspect, but it should be appreciated that for example, the former circuit configuration (see FIG. 2(a)) maybe used for both the first and second band-pass filters.

First, the configuration of the first band-pass filter having the equivalent circuit in FIG. 2(a) will be described.

The capacitance 201 is an input and output capacitive conductor formed by the capacitive conductors 120 and 124 (see FIG. 1). Further, the capacitance 202 is an input and output capacitive conductor formed by the capacitive conductors 121 and 125 (see FIG. 1).

The capacitance 208 is an interstage capacitive conductor by the capacitive conductors 133 and 135 (see FIG. 1).

The capacitance 203 is a resonator capacitive conductor formed by the grounding conductor 137 (see FIG. 1), the grounding conductor 142 (see FIG. 1), and the capacitive conductor 138 (see FIG. 1), located between the grounding conductor 137 and 142. Further, the capacitance 204 is a resonator capacitive conductor formed by the grounding conductor 137 (see FIG. 1), the grounding conductor 142 (see FIG. 1), and the capacitive conductor 139 (see FIG. 1) located between the grounding conductor 137 and 142.

Inductors 205 and 206 are formed by the strip line conductors 128 and 129 (see FIG. 1).

Furthermore, the capacitances 201 and 202 are connected to the input and output terminals 111 and 112 (see FIG. 1), respectively. Further, the inductor 205 and the capacitance 203 are connected in parallel, the inductor 206 and the capacitance 204 are connected in parallel, and these inductors and capacitances are coupled together by the capacitance 208, an interstage capacitive conductor, to constitute a two-staged polarized band-pass filter. Further, the mutual inductor 207 acts between the inductors 205 and 206, and the capacitance 208 connected in parallel to the mutual inductor 207 constitutes a resonance circuit.

In this manner, an attenuating pole is formed on a low frequency side of the pass band to constitute the first band-pass filter, which has the equivalent circuit in FIG. 2(a).

Then, the second band-pass filter, which has the equivalent circuit in FIG. 2(b), will be described.

The capacitance 209 is an input and output capacitive conductor formed by the capacitive conductors 122 and 126 (see FIG. 1). Further, the capacitance 210 is an input and output capacitive conductor formed by the capacitive conductors 123 and 127 (see FIG. 1).

The capacitance 216 is a cross coupling capacitive conductor formed by the grounding conductors 134 and 136 (see FIG. 1).

The capacitance 211 is a resonator capacitive conductor formed by the grounding conductor 137 (see FIG. 1), the grounding conductor 142 (see FIG. 1), and the capacitive conductor 140 (see FIG. 1), located between the grounding conductor 137 and 142. Further, the capacitance 212 is a resonator capacitive conductor formed by the grounding conductor 137 (see FIG. 1), the grounding conductor 142 (see FIG. 1), and the capacitive conductor 141 (see FIG. 1) located between the grounding conductor 137 and 142.

Inductors 213 and 214 are formed by the strip line conductors 131 and 132 (see FIG. 1). Furthermore, the capacitances 209 and 210 are connected to the input and output terminals 113 and 114 (see FIG. 1), respectively. Further, the inductor 213 and the capacitance 211 are connected in parallel, and the inductor 214 and the capacitance 212 are connected in parallel, thereby constitute a two-staged polarized band-pass filter. Further, the mutual inductor 215 acts between the inductors 213 and 214, and the capacitive conductor 136 (see FIG. 1) which forms the capacitance 216, a cross coupling capacitive conductor, is connected to the input and output terminal 114 (see FIG. 1) to constitute a resonance circuit.

In this manner, an attenuating pole is formed on a high frequency side of the pass band to constitute the second band-pass filter, which has the equivalent circuit in FIG. 2(b).

Further, the strip line conductor 130, formed on the dielectric layer 104, is grounded via the plurality of via conductors to act as a shielding conductor that inhibits the electromagnetic coupling between the strip line conductors 128 and 129, which constitute the first band-pass filter, and the strip line conductors 131 and 132, which constitute the second band-pass filter.

As described above, according to Embodiment 1, a laminated band-pass filter having two band-pass filters can be constructed without reducing the interval between the internal grounding conductors. This construction prevents the Q factor of the strip line conductors, which constitute the two band-pass filters, from decreasing, and provides a laminated band-pass filter provided with two small-loss band-pass filters.

In the above described embodiment, the strip line conductor 130, which acts as a shielding conductor, is connected to the internal grounding conductor 137 via the three via conductors (see FIG. 1). However, the present invention is not limited to this aspect, but the strip line conductor 130, which acts as a shielding conductor, may be grounded via an external conductor.

Further, in the above described embodiment, those ends of the strip line conductors 128 and 129 which are located on the same side are connected to the internal grounding conductor 119 (see FIG. 1). However, the present invention is not limited to this aspect, those ends of the strip line conductors 128 and 129 which are located on the different sides may be connected to the internal grounding conductor 119. If those ends of the strip line conductors 128 and 129 which are located on the different sides is thus connected to the internal grounding conductor 119, an available band is widened compared to the case in which those ends of the strip line conductors 128 and 129 which are located on the same side are connected to the internal grounding conductor 119.

(Embodiment 2)

A laminated band-pass filter according to Embodiment 2 of the present invention will be described below with reference to the drawings.

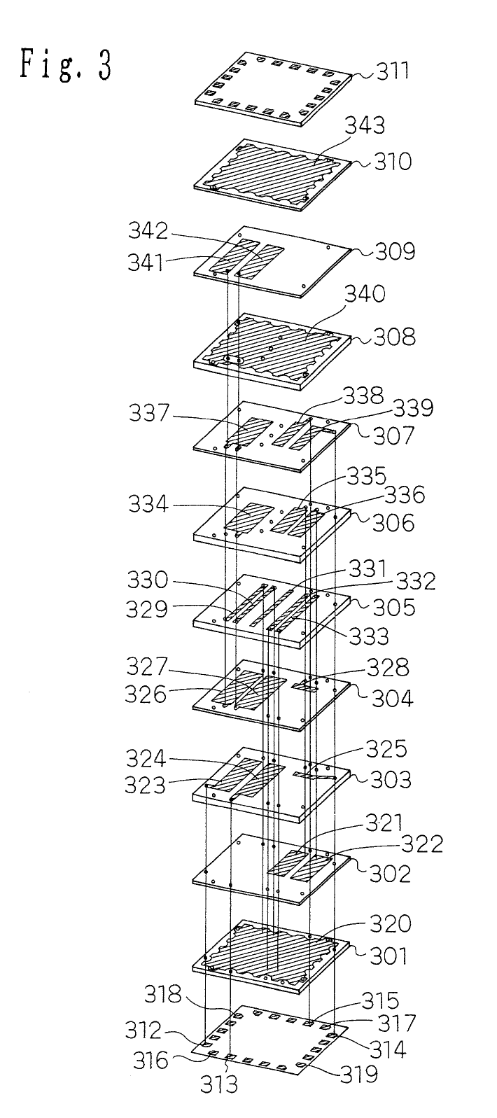

FIG. 3 is an exploded perspective view of the laminated band-pass filter according to Embodiment 2 of the present invention. As shown in this figure, the laminated band-pass filter according to Embodiment 2 of the present invention comprises sequentially laminated dielectric layers 301 to 311, and the integrated device has a size of 5.0×5.0 mm and a height of 0.8 mm. Further, each dielectric layer is composed of a crystal phase having a dielectric constant εr of 7 and a glass phase. The crystal phase is composed of Mg₂SiO₄, whereas the glass phase is composed of Si—Ba—La—B—O-system. The integrated device has input and output terminals 312 to 315 and grounding terminals 316 to 319 formed on a bottom surface thereof.

The dielectric layers 301, 308, and 310 have internal grounding conductors 320, 340, and 343, respectively, arranged on top surfaces thereof and connected to the grounding terminals 316 to 319 via via conductors. The dielectric layer 302 has capacitive conductors 321 and 322 arranged on a top surface thereof, and the dielectric layer 303 has capacitive conductors 323 to 325 arranged on a top surface thereof. All these capacitive conductors are connected to the input and output terminals 312 to 314, respectively, via via conductors.

The dielectric layer 304 has capacitive conductors 326 to 328 arranged on a top surface thereof, and the dielectric layer 305 has strip line conductors 329 to 333 arranged on a top surface thereof. Further, the dielectric layer 306 has capacitive conductors 334 and 336 arranged on a top surface thereof, the dielectric layer 307 has capacitive conductors 337 to 339 arranged on a top surface thereof, and the dielectric layer 309 has capacitive conductors 341 and 342 arranged on a top surface thereof.

Furthermore, the strip line conductor 329 has one end thereof connected to the internal grounding conductor 320 via a via conductor and the other end thereof connected to each of the capacitive conductors 326, 337, and 341 via a via conductor. Likewise, the strip line conductor 330 has one end thereof connected to the internal grounding conductor 320 via a via conductor and the other end thereof connected to each of the capacitive conductors 327, 334, and 342 via a via conductor. The strip line conductor 332 has one end thereof connected to the internal grounding conductor 320 via a via conductor and the other end thereof connected to each of the capacitive conductors 321, 328, and 335 via a via conductor. The strip line conductor 333 has one end thereof connected to the internal grounding conductor 320 via a via conductor and the other end thereof connected to each of the capacitive conductors 322 and 336 via a via conductor.

Further, the capacitive conductors 338 and 339 are arranged opposite the capacitive conductors 335 and 336 and connected to the input and output terminals 315 and 314, respectively, via via conductors. The strip line conductor 331 is connected to the internal grounding conductor 340 via three via conductors.

The strip line conductor 331 corresponds to a shielding conductor according to the present invention, and the input and output terminals 312 to 315 correspond to input and output terminals according to the present invention. The grounding terminals 316 to 319 correspond to grounding terminals according to the present invention, the capacitive conductors 321 to 328, 334 to 339, 341, and 342 correspond to capacitive conductors according to the present invention, and the strip line conductors 329 to 333 correspond to strip line conductors according to the present invention. Further, the dielectric layers 301 to 311 correspond to dielectric layers according to the present invention, the internal grounding conductors 320, 340, and 343 correspond to grounding conductors according to the present invention, and the internal grounding conductors 320 and 343 correspond to two grounding conductors according to the present invention having a shielding function.

An equivalent circuit of the laminated band-pass filter in FIG. 3 is similar to that of Embodiment 1 and is shown in FIGS. 2(a) and 2(b).

This circuit differs from Embodiment 1 in that the capacitive conductors of the two band-pass filters which have similar circuit functions are arranged on different planes.

That is, the capacitive conductors 341 and 342, which form the capacitances 203 and 204, the resonator capacitive conductors of the first band-pass filter, are arranged on the dielectric layer 309, and the capacitive conductors 321 and 322, which form the capacitances 211 and 212, the resonator capacitive conductors of the second band-pass filter, are arranged on the dielectric layer 302. Further, the capacitances 201 and 202, the input and output capacitive conductors of the first band-pass filter, are arranged on the dielectric layer 304, and the capacitances 209 and 210, the input and output capacitive conductors of the second band-pass filter, are arranged on the dielectric layer 307.

As described above, according to Embodiment 2, not only effects similar to those of Embodiment 1 of the present invention are produced but also the capacitive conductors having similar circuit functions are formed on the different dielectric layers, thereby enabling the interference between the capacitive conductors constituting the two band-pass filters to be reduced to ensure that the two band-pass filters are isolated from each other.

(Embodiment 3)

A laminated filter according to Embodiment 3 of the present invention will be described below with reference to the drawings.

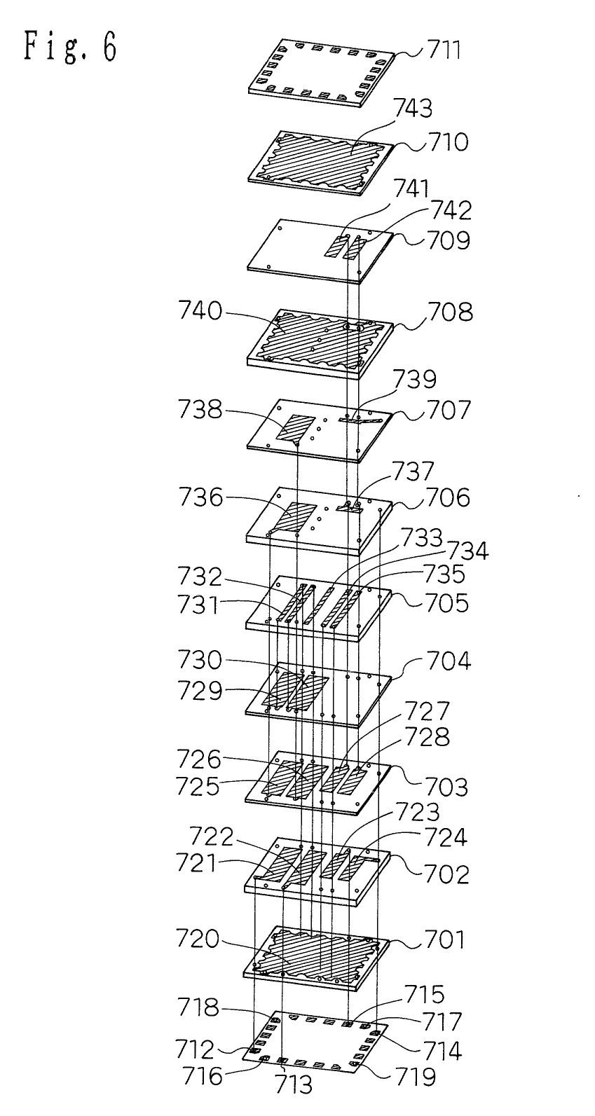

FIG. 6 is an exploded perspective view of the laminated filter according to Embodiment 3 of the present invention.

In this embodiment, the first filter (in the left of the drawing) is composed of a band elimination filter, whereas the second filter (in the right of the drawing) is composed of a band-pass filter.

As shown in FIG. 6, the laminated filter according to Embodiment 3 of the present invention comprises sequentially laminated dielectric layers 701 to 711.

Here, the integrated device has a size of 5.0×5.0 mm and a height of 0.8 mm. Further, each dielectric layer is composed of a crystal phase having a dielectric constant εr of 7 and a glass phase. The crystal phase is composed of Mg₂SiO₄, whereas the glass phase is composed of Si—Ba—La—B—O-system.

The integrated device has input and output terminals 712 to 715 and grounding terminals 716 to 719 formed on a bottom surface thereof.

The dielectric layers 701, 708, and 710 have internal grounding conductors 720, 740, and 743, respectively, arranged on top surfaces thereof and connected to the grounding terminals 716 to 719 via via conductors. The dielectric layer 702 has capacitive conductors 721 to 724 arranged on a top surface thereof and connected to the grounding terminals 712 to 714 via via conductors.

The dielectric layer 703 has capacitive conductors 725 to 728 arranged on a top surface thereof, and the dielectric layer 704 has capacitive conductors 729 and 730 arranged on a top surface thereof. Further, the dielectric layer 705 has strip line conductors 731 to 735 arranged on a top surface thereof, and the dielectric layer 706 has capacitive conductors 736 and 737 arranged on a top surface thereof. Furthermore, the dielectric layer 707 has capacitive conductors 738 and 739 arranged on a top surface thereof, and the dielectric layer 709 has capacitive conductors 741 and 742 arranged on a top surface thereof.

The strip line conductor 731 has one end thereof connected to the internal grounding conductor 720 via a via conductor and the other end thereof connected to the capacitive conductor 729 via a via conductor. Further, the strip line conductor 732 has one end thereof connected to the internal grounding conductor 720 via a via conductor and the other end thereof connected to the capacitive conductor 730 via a via conductor. Furthermore, the strip line conductor 734 has one end thereof connected to the internal grounding conductor 720 via a via conductor and the other end thereof connected to each of the capacitive conductors 727, 737, and 741 via a via conductor. Moreover, the strip line conductor 735 has one end thereof connected to the internal grounding conductor 720 via a via conductor and the other end thereof connected to each of the capacitive conductors 728, 739, and 742 via a via conductor.

The capacitive conductor 725 is connected to the capacitive conductor 736 via a via conductor, and the capacitive conductor 726 is connected to the capacitive conductor 738 via a via conductor. Further, the capacitive conductor 739 is arranged opposite the capacitive conductor 737 and connected to the input and output terminal 714 via a via conductor. Furthermore, the strip line conductor 733 is connected to the internal grounding conductor 740 via three via conductors.

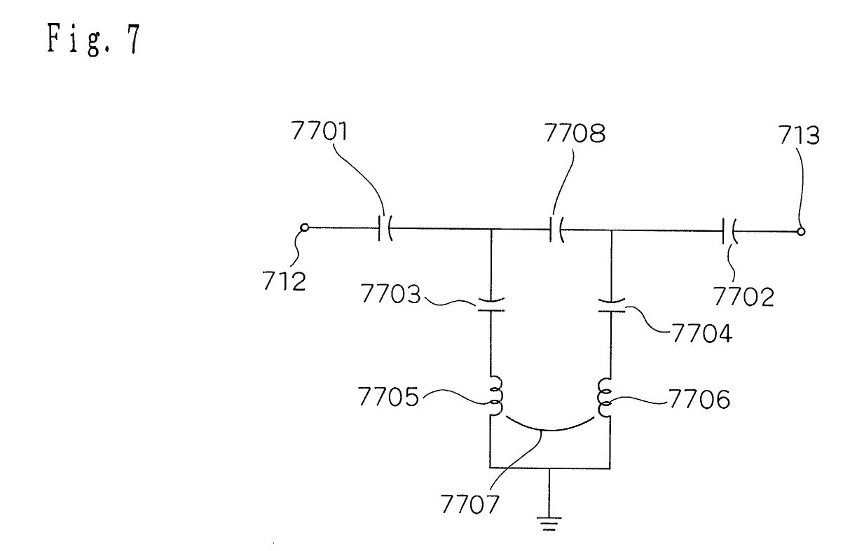

Now, the circuit configuration of the laminated filter constructed as described above will be described with reference to FIGS. 2(b) and 7.

This circuit differs from Embodiments 1 and 2, described previously, in that one of the two filters is composed of a band elimination filter. That is, in the laminated filter (see FIG. 6) of this embodiment, the first filter (in the left of the drawing) is composed of a band elimination filter, whereas the second filter (in the right of the drawing) is composed of a band-pass filter.

A capacitance 7701 is formed by the capacitive conductors 721 and 725, and a capacitance 7702 is formed by the capacitive conductors 722 and 726. Further, a capacitance 7708 is formed by the capacitive conductors 736 and 738. Furthermore, a capacitance 7703 is formed by the capacitive conductors 725 and 729, and a capacitance 7704 is formed by the capacitive conductors 726 and 730. In this case, the capacitive conductor 725 is shared to form the capacitances 7701 and 7703, and the capacitive conductor 726 is shared to form the capacitances 7702 and 7704, thereby reducing the number of parts required.

Further, inductors 7705 and 7706 are formed by the strip line conductors 731 and 732.

The capacitances 7701 and 7702 are connected to the input and output terminals 712 and 713, respectively. Further, the inductor 7705 and the capacitance 7703 are connected together in series, the inductor 7706 and the capacitance 7704 are connected together in series, and these inductors and capacitances are coupled together by a capacitance 7708 to constitute a two-stage band elimination filter.

A mutual inductor 7707 acts between the inductors 7705 and 7706, and the capacitance 7708, connected in parallel to the mutual inductor 7707, constitutes a resonance circuit. Thus, a stop band is formed to form a first filter (band elimination filter) having the equivalent circuit in FIG. 7.

Next, the capacitance 209 is formed by the capacitive conductors 723 and 727, the capacitance 210 is formed by the capacitive conductors 724 and 728, and the capacitance 216 is formed by the capacitive conductors 737 and 739. Further, the capacitance 211 is formed by the internal grounding conductors 740 and 743 and the capacitive conductor 741, formed between the internal grounding conductors 740 and 743. Furthermore, the capacitance 212 is formed by the internal grounding conductors 740 and 743 and the capacitive conductor 742, formed between the internal grounding conductors 740 and 743.

The inductors 213 and 214 are formed by the strip line conductors 734 and 735, respectively. Further, the capacitances 209 and 210 are connected to the input and output terminals 215 and 214, respectively. Furthermore, the inductor 213 and capacitance 211 are connected together in parallel and the inductor 214 and capacitance 212 are connected together in parallel to constitute a two-stage polarized band-pass filter.

The mutual inductor 215 acts between the inductors 213 and 214, and the capacitive conductor 739, which constitutes the cross coupling capacitance 216, is connected to the input and output terminal 714 to constitute a resonance circuit. Thus, an attenuating pole is formed on the high frequency side of the pass band to form a second filter (band-pass filter) having the equivalent circuit in FIG. 2(b).

The strip line conductor 733, formed on the dielectric layer 705, is grounded via the plurality of via conductors to act as a shielding conductor that inhibits the strip line conductors 731 and 732 and the strip line conductors 734 and 735, which constitute the two respective filters, from being electromagnetically coupled together.

The strip line conductor 733 corresponds to a shielding conductor according to the present invention, and the input and output terminals 712 to 715 correspond to input and output terminals according to the present invention. The grounding terminals 716 to 719 correspond to grounding terminals according to the present invention, the capacitive conductors 721 to 730, 736 to 739, 741, and 742 correspond to capacitive conductors according to the present invention, and the strip line conductors 731 to 735 correspond to strip line conductors according to the present invention. Further, the dielectric layers 701 to 711 correspond to dielectric layers according to the present invention, the internal grounding conductors 720, 740, and 743 correspond to grounding conductors according to the present invention, and the internal grounding conductors 720 and 743 correspond to two grounding conductors according to the present invention having a shielding function.

As described above, Embodiment 3 of the present invention not only produces the same effects as Embodiments 1 and 2, described above, but also enables two filters having different circuit configurations and different functions to be installed in one device, thereby increasing the degree of freedom of system design.

Embodiments 1 to 3 has been described in detail.

In the above described embodiments, each of the dielectric layers is, by way of example, a dielectric sheet composed of a crystal phase having a dielectric constant εr of 7 and a dielectric loss tan δ of 2.0×10⁻⁴ as well as a glass phase. However, similar effects are produced by using a dielectric sheet composed of a crystal phase having a dielectric constant εr of 5 to 10 and a glass phase. Further, by way of example, the crystal phase is Mg₂SiO₄, and the glass phase is an Si—Ba—La—B—O system. Similar effects are produced by using a crystal phase containing at least one of Al₂O₃, MgO, SiO₂, and ROa and a glass phase. Here, in ROa, R denotes an element selected from a group consisting of La, Ce, Pr, Nd, Sm, and Gd, and a denotes a numerical value stoichiometrically determined depending on the valence of R. Further, in the above description, the integrated device has a size of 5.0×5.0 mm and a height of 0.8 mm by way of example, but similar effects are produced regardless of the size or height of the integrated device.

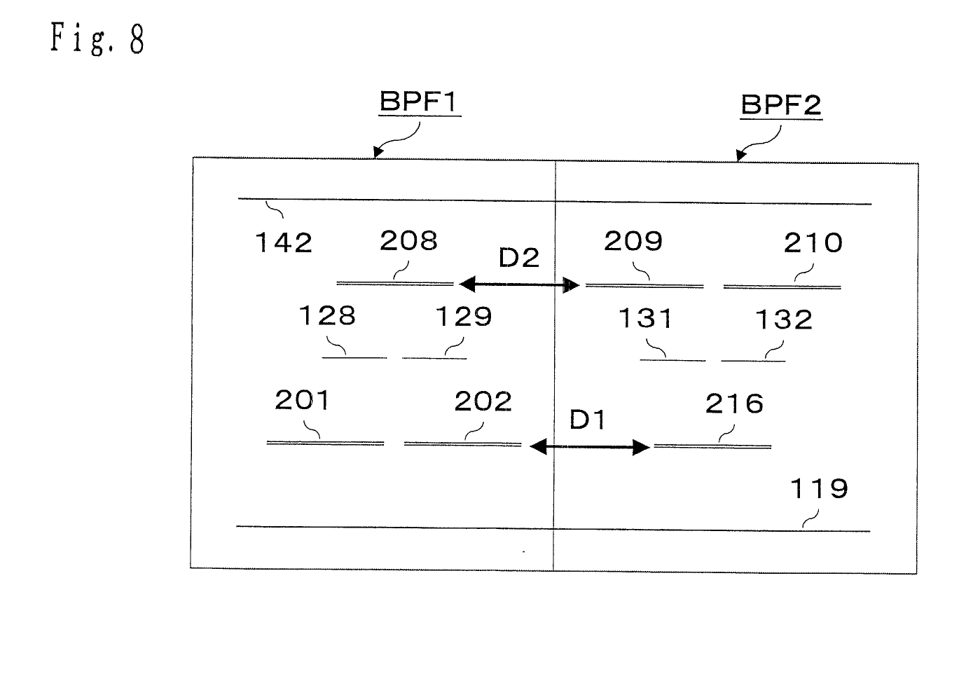

Further, in the above described Embodiment 1 of the present invention, for example, (1) the layer having the capacitances 201 and 202 (see FIG. 2(a)) the input and output capacitive conductors of the first band-pass filter and the layer having the capacitances 209 and 210 (see FIG. 2(b)), the input and output capacitive conductors of the second band-pass filter are present in the equal layer of the integrated device, and (2) the layer having the capacitance 208(see FIG. 2(a)), the interstage capacitive conductor of the first band-pass filter and the layer having the capacitance 216 (see FIG. 2(b)), the cross coupling capacitive conductors of the second band-pass filter are present in the equal layer of the integrated device. However, the present invention is not limited to this aspect, but as shown in FIG. 8 illustrating another example of the laminated structure of the laminated band-pass filter according to Embodiment 1 of the present invention, (1) the layer having the capacitances 201 and 202, the input and output capacitive conductors of the first band-pass filter BPF1 and the layer having the capacitances 209 and 210, the input and output capacitive conductors of the second band-pass filter BPF2 may be present in different layers of the integrated device, and (2) the layer having the capacitance 208, the interstage capacitive conductor and the layer having the capacitance 216, the cross coupling capacitive conductors may be present in different layers of the integrated device (in FIG. 8, the capacitances 201 and 202 and the capacitance 216 are disposed on the same layer with a sufficient distance D1 therebetween, whereas the capacitance 208 and the capacitances 209 and 210 are disposed on the same layer with a sufficient distance D2 therebetween). Thus, if the capacitive conductors having similar circuit functions are formed on different dielectric layers, the interference between the capacitive conductors constituting the two filters can be further reduced, thereby ensuring that the two filters are isolated from each other. Of course, if the at least one of the first and second filters of the present invention is a band elimination filter, similar arrangements further ensure that the two filters are isolated from each other.

Further, the two filters in the laminated filter of each embodiment described above may have different frequency characteristics. If the two filters have different frequency characteristics, the conductors constituting the filter using lower frequencies as a pass band may have a larger occupied volume than the conductors constituting the other filter. However, if the first and second filters of the present invention are of the same type (for example, if both first and second filters are band elimination filters), an arrangement similar to the one described above is expected to improve the filter characteristics, but if the first and second filters of the present invention are of different types (for example, if the first filter is a band-pass filter and the second filter is a band elimination filters), this arrangement may not be effective because the circuit configurations will be different. More specifically, the above described improvement of the filter characteristics is a decrease in loss in the pass band if a band-pass filter is used or a sufficient amount of attenuation in the stop band if a band elimination filter is used.

Further, circuit elements such as capacitors or inductors may be arranged which are matched to an LNA (Low Noise Amplifier) or mixer preceding or following the laminated filter of each of the above described embodiments so that the input and output terminals of the two filters of the laminated filter are electrically connected to the circuit elements.

A integrated device with an IC (Integrated Circuit) belongs to the present invention, the device being formed by mounting the IC containing an LNA or a mixer, on a integrated device containing the laminated filter of the present invention and connecting the IC to the laminated filter.

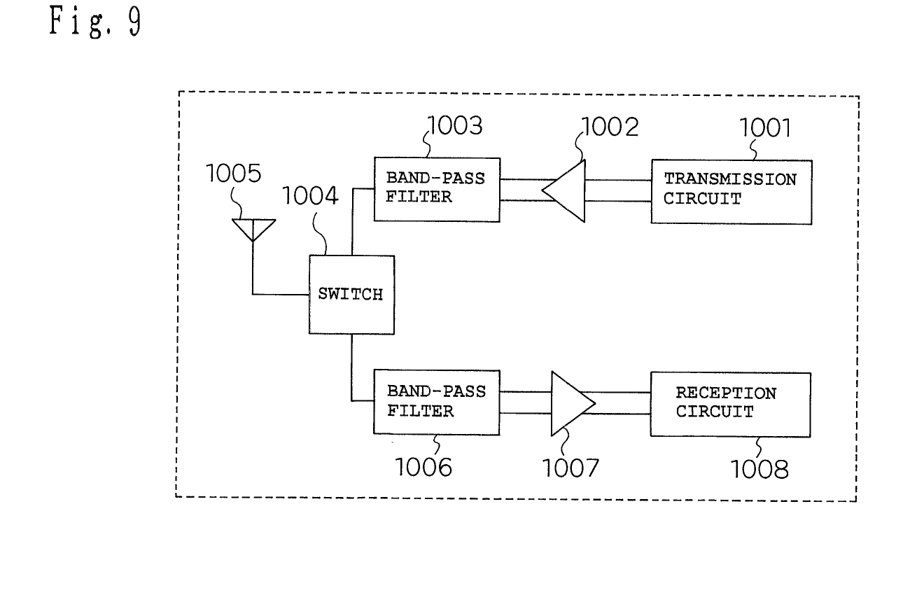

Further, a communication apparatus such as the one shown in FIG. 9 illustrating the configuration of a communication apparatus according to an embodiment of the present invention belongs to the present invention, the apparatus comprising a transmission circuit 1001 for executing transmissions using an amplifier 1002, a switch 1004, and an antenna 1005, a reception circuit 1008 for executing receptions using the antenna 1005, the switch 1004, and an amplifier 1007, a band-pass filter 1003, for filtering transmitted signals used for transmissions, and a band-pass filter 1006 for filtering received signals used for receptions.

As is apparent from the above description, the present invention has the advantage of being able to provide a small-sized and small-loss laminated filter, integrated device, and communication apparatus.

What is claimed is:

1. A laminated filter comprising:
a plurality of grounding conductors formed inside or outside a integrated device formed by laminating and integrating a plurality of dielectric layers together;
a first filter sandwiched between two of said grounding conductors which have a shielding function; and
a second filter sandwiched between said two grounding conductors.

2. The laminated filter according to claim 1, wherein said first filter is a band-pass filter, and
said second filter is a band-pass filter.

3. The laminated filter according to claim 2, wherein said first filter and said second filter are formed in different areas with a boundary between these areas corresponding to a predetermined cross section substantially perpendicular to said two grounding conductors.

4. The laminated filter according to claim 3, further comprising a shielding conductor formed substantially in said predetermined cross section and connected to said plurality of grounding conductors to shield electromagnetic induction between said first filter and said second filter.

5. The laminated filter according to claim 4, wherein via conductors are used to connect the shielding conductor to said grounding conductors.

6. The laminated filter according to claim 2, wherein some of said plurality of grounding conductors are formed inside said integrated device,
said first filter has a plurality of input and output terminals formed inside or outside said integrated device, a grounding terminal formed inside or outside said integrated device, a capacitive conductor formed inside said integrated device, and a plurality of strip line conductors formed inside said integrated device,
said grounding terminal is electrically connected to the grounding conductors formed inside said integrated device, and
said plurality of strip line conductors each have one end electrically connected to said capacitive conductor and the other end electrically connected to the grounding conductors formed inside said integrated device.

7. The laminated filter according to claim 6, wherein said plurality of strip line conductors are two strip line conductors installed in parallel, and
the other ends of said two parallel strip line conductors are not adjacent to each other.

8. The laminated filter according to claim 6, wherein said plurality of input and output terminals are two input and output terminals installed in proximity to each other,
said grounding terminal is provided between said two input and output terminals installed in proximity to each other.

9. The laminated filter according to claim 6, wherein said second filter has a plurality of input and output terminals formed inside or outside said integrated device, and
a plurality of input and output terminals of said first filter and a plurality of input and output terminals of said second filter are provided in the same layer of said integrated device symmetrically with respect to the center of said layer.

10. The laminated filter according to claim 6, further comprising a predetermined circuit element electrically connected to said plurality of input and output terminals.

11. The laminated filter according to claim 2, wherein said first filter has a layer having a resonator capacitive conductor required to constitute a resonator, a layer having input and output capacitive conductors connected to the input and output terminals, and a layer having an interstage capacitive conductor or a cross coupling capacitive conductor,
said second filter has a layer having a resonator capacitive conductor required to constitute a resonator, a layer having input and output capacitive conductors connected to the input and output terminals, and a layer having an interstage capacitive conductor or a cross coupling capacitive conductor,
(a) the layer having the resonator capacitive conductor of said first filter and the layer having the resonator capacitive conductor of said second filter are present in different layers of said integrated device, (b) the layer having the input and output capacitive conductors of said first filter and the layer having the input and output capacitive conductors of said second filter are present in different layers of said integrated device, or (c) the layer having the interstage capacitive conductor or cross coupling capacitive conductor of said first filter and the layer having the interstage capacitive conductor or cross coupling capacitive conductor of said second filter are present in different layers of said integrated device.

12. The laminated filter according to claim 2, wherein said first filter has a plurality of strip line conductors formed substantially midway between said two grounding conductors in a thickness direction of said integrated device.

13. The laminated filter according to claim 2, wherein said first filter has a plurality of capacitive conductors and a plurality of strip line conductors, and
of said plurality of capacitive conductors, the interstage capacitive conductor, cross coupling capacitive conductor, and input and output capacitive conductors are formed substantially midway between either of said two grounding conductors and said plurality of strip line conductors in the thickness direction of said integrated device.

14. The laminated filter according to claim 2, wherein said first filter has a plurality of capacitive conductors and a plurality of strip line conductors, and
a predetermined one of those of said plurality of capacitive conductors which are connected to said strip line conductors electrically in parallel is formed opposite either of said two grounding conductors.

15. The laminated filter according to claim 14, further comprising a predetermined grounding conductor formed so that said predetermined capacitive conductor is sandwiched between said predetermined grounding conductor and either of said two grounding conductors.

16. The laminated filter according to claim 2, wherein said first filter and said second filter use different frequency bands as pass bands.

17. The laminated filter according to claim 16, wherein one of said first and second filters which use a lower frequency band as a pass band has a larger occupied volume in said integrated device.

18. The laminated filter according to claim 2, wherein a crystal phase forming the dielectric layers of said integrated device has any of Al₂O₃, MgO, SiO₂, and ROa for R denoting at least one of La, Ce, Pr, Nd, Sm, and Gd and a denoting a numerical value stoichiometrically determined depending on the valence of said R.

19. The laminated filter according to claim 1, wherein said first filter is a band-pass filter, and said second filter is a band elimination filter.

20. The laminated filter according to claim 1, wherein said first filter is a band elimination filter, and
said second filter is a band elimination filter.

21. A integrated device comprising:
said integrated device containing the laminated filter according to claim 1, and
an integrated circuit mounted in said integrated device.

22. A communication apparatus comprising:
transmitting and receiving means of executing transmission and/or reception, and
the laminated filter according to claim 1 which filters a transmitted signal used for said transmission and/or a received signal used for said reception.
